(19) United States
(12) Patent Application Publication
(10) Pub. No.: US 2015/0295098 A1
(43) Pub. Date: Oct. 15, 2015

(54) CHIP PACKAGE

(71) Applicant: FUJITSU LIMITED, Kawasaki-shi (JP)

(72) Inventor: Asako TODA, Santa Clara, CA (US)

(73) Assignee: FUJITSU LIMITED, Kawasaki-shi (JP)

(21) Appl. No.: 14/251,212

(22) Filed: Apr. 11, 2014

(51) Int. Cl. H01L 31/02; G02B 6/12; G02B 6/42; H01L 31/167

(52) U.S. Cl. CPC H01L 31/02005; H01L 31/167; G02B 6/12; G02B 6/4295

(57) ABSTRACT

A chip package includes a first silicon die including silicon photonics circuitry configured to manipulate optical signals and a second silicon die electrically coupled to the first silicon die. The second silicon die may include electronic circuitry configured to provide electrical signals used by the silicon photonics circuitry to manipulate the optical signals or electrical signals generated by the silicon photonics circuitry based on the optical signals. The chip package may also include a third silicon die electrically coupled to the second silicon die by one or more transmission lines. The third silicon die may include a processing unit configured to process digital signals based on the electrical signals associated with the optical signals and to provide the digital signals to or to receive the digital signals from the second silicon die.

### FIELD

The embodiments discussed herein are related to a chip package.

### BACKGROUND

Chip-to-chip interconnects are used to electrically interconnect heterogeneous components in environments including integrated circuit (IC) chip packages. Chip-to-chip interconnects in some IC chip packages may be relatively long and the length of the chip-to-chip interconnects may adversely impact and/or prevent high bandwidth data communications over the chip-to-chip interconnects between interconnected chips.

Other IC chip packages may have relatively short chip-to-chip interconnects at the expense of relatively high thermal coupling between the chips. When the performance of one of the interconnected chips is temperature-sensitive and the other of the interconnected chips is subject to temperature fluctuations, the relatively high thermal coupling between the chips and the temperature fluctuations may adversely affect the performance of the temperature-sensitive chip.

The subject matter claimed herein is not limited to embodiments that solve any disadvantages or that operate only in environments such as those described above. Rather, this background is only provided to illustrate one example technology area where some embodiments described herein may be practiced.

### SUMMARY

According to an aspect of an embodiment, a chip package includes a first silicon die including silicon photonics circuitry configured to manipulate optical signals and a second silicon die electrically coupled to the first silicon die. The second silicon die may include electronic circuitry configured to provide electrical signals used by the silicon photonics circuitry to manipulate the optical signals or electrical signals generated by the silicon photonics circuitry based on the optical signals. The chip package may also include a third silicon die electrically coupled to the second silicon die by one or more transmission lines. The third silicon die may include a processing unit configured to process digital signals based on the electrical signals associated with the optical signals and to provide the digital signals to or to receive the digital signals from the second silicon die.

The object and advantages of the embodiments will be realized and achieved at least by the elements, features, and combinations particularly pointed out in the claims.

It is to be understood that both the foregoing general description and the following detailed description are exemplary and explanatory and are not restrictive of the invention, as claimed.

### BRIEF DESCRIPTION OF THE DRAWINGS

Example embodiments will be described and explained with additional specificity and detail through the use of the accompanying drawings in which:

FIG. 1A illustrates a top view of an example chip package;

FIG. 1B illustrates a cross-sectional view of the example chip package of FIG. 1A;

FIG. 2 illustrates an example silicon die;

FIG. 3 illustrates another example silicon die;

FIG. 4 illustrates another example silicon die;

FIG. 5 illustrates a cross-sectional view of another example chip package;

FIG. 6 illustrates a cross-sectional view of another example chip package;

FIG. 7 illustrates a cross-sectional view of another example chip package; and

FIG. 8 illustrates a flow diagram of an example method of forming a chip package.

### DESCRIPTION OF EMBODIMENTS

According to an aspect of an embodiment, a chip package disclosed herein includes a first silicon die that includes silicon photonics circuitry, a second silicon die that includes electronic circuitry that supports the photonics circuitry, and a third silicon die that includes a processing unit, such as a central processing unit. The chip package may further include a connector such that the chip package may operate as a high-speed optical interconnect with an integrated central-processing unit.

In the chip package, the third silicon die that includes the processing unit may be spatially separated from the first and second silicon dies to help to reduce heat generated by the third silicon die from affecting the first and second silicon dies. To help to overcome losses associated with transferring high speed data signals from the third silicon die to the first and second silicon dies, such as data signals with data rates higher than 10 gigabits per second (Gbps), the second silicon die may have electrical circuitry configured to process high-speed signals and to provide the data signals to the photonics circuitry at data rates that are higher than would be possible if the electrical circuitry and the photonics circuitry were included on the same silicon die.

Embodiments of the present disclosure will be explained with reference to the accompanying drawings. With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

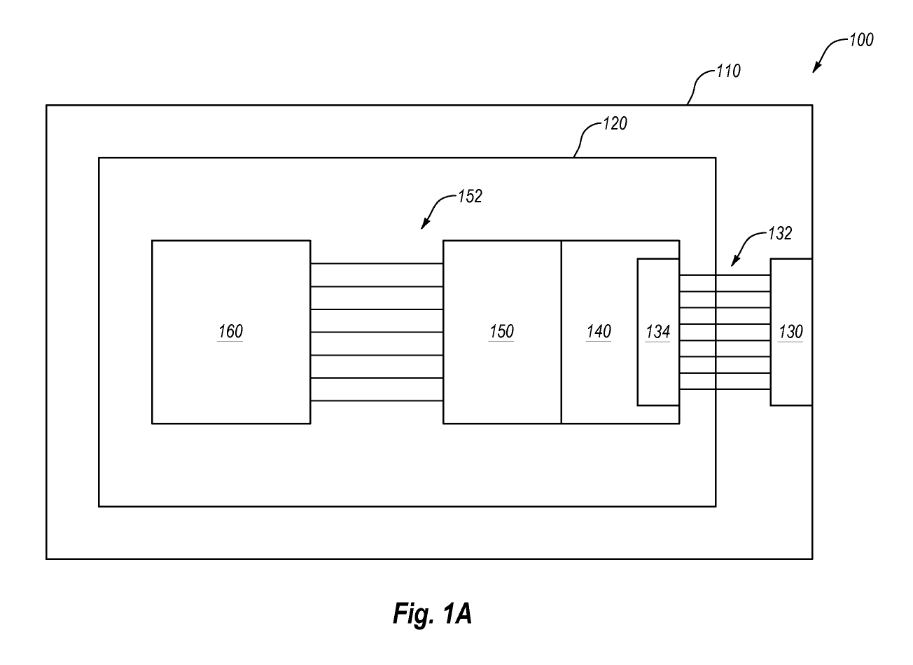

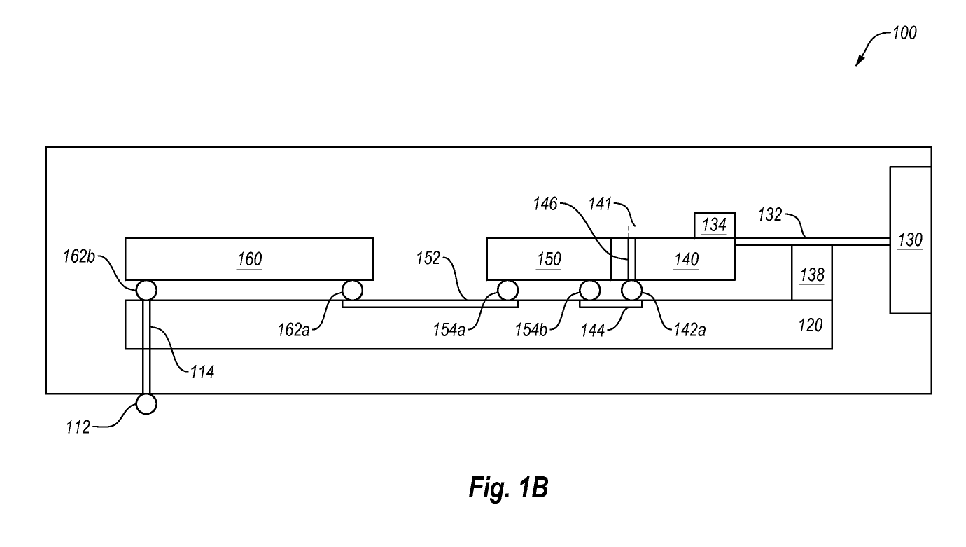

FIG. 1A illustrates a top view of an example chip package 100, arranged in accordance with at least one embodiment described herein. The chip package 100 may include a first silicon die 140, a second silicon die 150, and a third silicon die 160. The first, second, and third silicon dies 140, 150, and 160 may be formed independently, using the same or different processing techniques.

The first silicon die 140 may be formed to include photonics circuitry. In this and other embodiments, the photonics circuitry may use silicon as an optical medium to affect optical signals. For example, the first silicon die 140 may include optical components formed in silicon that manipulate optical signals. In particular, the first silicon die 140 may include optical components for manipulating optical signals for use within an optical network. For example, the optical components may be used to generate optical signals from analog signals for transmission over optical fibers within an optical network. Alternately or additionally, the optical components may be used for receiving optical signals transmitted over an optical network and converting the optical signals to analog signals. The optical components may include one or more of a photodiode, an optical multiplexer, an optical modulator, an optical demultiplexer, among other optical components.

The first silicon die 140 may be manufactured using a variety of silicon processing techniques. For example, the first silicon die 140 may be manufactured using a 65 nanometer (nm) process, 90 nm process, 130 nm process, 180 nm process, 250 nm process, or other process on silicon wafers of varying sizes. The first silicon die 140 may be encapsulated and have interconnect components formed thereon before being integrated into the chip package 100. Alternately or additionally, the first silicon die 140 may not be encapsulated and may have interconnect components formed thereon before being integrated into the chip package 100. Alternately or additionally, the first silicon die 140 may have interconnect components formed thereon but may not be encapsulated before being integrated into the chip package 100.

The second silicon die 150 may be formed to include electronic circuitry configured to support the photonic operations performed by the first silicon die 140. For example, the second silicon die 150 may include a transimpedance amplifier, a driver, a clock and data recovery circuit, a clock synthesizer circuit, a multiplexer, a demultiplexer, an analog-to-digital converter (ADC), a digital-to-analog converter (DAC), a temperature sensor, control logic for the photonic operations performed by the first silicon die 140, among other electronic circuitry. In general, the electronic circuitry on the second silicon die 150 may be configured to generate analog signals from digital signals that may be used to generate optical signals in the optical circuitry of the first silicon die 140 and/or condition analog signals resulting from optical signals from the optical circuitry of the first silicon die 140 and convert the analog signals to digital signals. For example, the electronic circuitry may receive digital signals on a parallel bus. The electronic circuitry may de-multiplex the digital signals, convert the de-multiplexed digital signals to analog signals, and process the analog signals for use by a laser diode to generate optical signals. As another example, the electronic circuitry may receive an analog signal from a photodiode in the first silicon die 140, process the analog signal, generate a digital signal based on the analog signal, and multiplex the digital signals for sending the digital signals over a parallel bus.

The second silicon die 150 may be manufactured using a variety of silicon processing techniques. For example, the second silicon die 150 may be manufactured using a 14 nm process, 22 nm process, 32 nm process, 45 nm process, 65 nm process, 90 nm process, 130 nm process, 180 nm process, 250 nm process, or another process on silicon wafers of varying sizes. The second silicon die 150 may be manufactured using the same or a different process than the first silicon die 140.

By manufacturing the first silicon die 140 using a process that is different from the process used to form the second silicon die 150, the electronic circuitry on the second silicon die 150 may process higher data rate signals than if the same process were used. For example, if the electronic circuitry of the second silicon die 150 was formed on the same silicon die as the photonic circuitry of the first silicon die 140, the process used to form the electronic circuitry and the photonic circuitry on the same die may result in electronic circuitry that is only able to process data rates that are lower than data rates that may be processed with electronic circuitry that is formed on a separate silicon die using a different process. For example, a process used to form the electronic circuitry and the photonic circuitry on the same die may be a 90 nm process. In contrast, when the electronic circuitry and the photonic circuitry are formed on separate silicon dies, a 32 nm process may be used to form the second silicon die 150 and a 90 nm process may be used to form the first silicon die 140. The electronic circuitry formed using the 32 nm process may be faster and consume less power than the electronic circuitry formed using the 90 nm process.

The second silicon die 150 may be encapsulated and may have interconnect components formed thereon before being integrated into the chip package 100. Alternately or additionally, the second silicon die 150 may not be encapsulated and may have interconnect components formed thereon before being integrated into the chip package 100. Alternately or additionally, the second silicon die 150 may have interconnect components formed thereon but may not be encapsulated before being integrated into the chip package 100.

The third silicon die 160 may be formed to include a processing unit that is a very-large-scale-integration (VLSI) processing unit configured to process digital signals based on instructions received from a set of instructions configured for the processing unit. The digital signals processed by the third silicon die 160 may be associated with the optical signals. For example, the digital signals generated or processed by the third silicon die 160 may be converted to electrical signals, e.g., analog signals, by the second silicon die 150 and may be conditioned to be used by the first silicon die 140 or other optical components, such as optical components 134, to generate optical signals that are manipulated by the optical components on the first silicon die 140. Alternately or additionally, optical signals manipulated by optical components on the first silicon die 140 may be converted to electrical signals, e.g., analog signals, that are converted to digital signals by the second silicon die 150 that are sent to the third silicon die 160 for processing.

The third silicon die 160 may be manufactured using a variety of silicon processing techniques. For example, the third silicon die 160 may be manufactured using a 14 nm process, 22 nm process, 32 nm process, 45 nm process, 65 nm process, 90 nm process, 130 nm process, 180 nm process, 250 nm process, or another process on silicon wafers of varying sizes. In some embodiments, the third silicon die 160 may be manufactured using the same or a different process than the first silicon die 140 and/or the second silicon die 150.

The third silicon die 160 may be encapsulated and may have interconnect components formed thereon before being integrated into the chip package 100. Alternately or additionally, the third silicon die 160 may not be encapsulated and may have interconnect components formed thereon before being integrated into the chip package 100. Alternately or additionally, the third silicon die 160 may have interconnect components formed thereon but may not be encapsulated before being integrated into the chip package 100.

The first, second, and third silicon dies 140, 150, and 160 may be supported in the chip package 100 by a substrate 120. The substrate 120 may be a silicon substrate with one or more redistribution layers. Alternately or additionally, the substrate may be an organic buildup substrate and/or a glass ceramic substrate. The redistribution layers may include bond pads coupled to traces for electrically coupling the first, second, and third silicon dies 140, 150, and 160. For example, multiple first traces 152 may electrically couple the second silicon die 150 and the third silicon die 160. In some embodiments, the first traces 152 may be referred to as transmission lines. Digital signals shared between the second silicon die 150 and the third silicon die 160 may be transmitted over the first traces 152.

The first, second, and third silicon dies 140, 150, and 160 and the substrate 120 may be encapsulated by an encapsulation 110. The encapsulation 110 may also encapsulate an optical fiber connector 130, jumper optical fibers 132, and other optical components 134. The optical fiber connector 130 may be coupled to the jumper optical fibers 132 and the jumper optical fibers 132 may be coupled to the optical components 134. The optical components 134 may be optically and/or electrically coupled to the first silicon die 140.

The optical fiber connector 130 may be configured to be coupled to optical fibers in an optical network such that optical signals on the optical fibers may be passed to the jumper optical fibers 132. Alternately or additionally, the optical fiber connector 130 may be configured to couple to optical fibers in an optical network such that optical signals generated by the chip package 100 may be passed from the jumper optical fibers 132 to the optical fibers in the optical network.

The optical components 134 may include a laser diode and an optical amplifier, among other optical components. The laser diode may be configured to generate optical signals that may be manipulated by the optical components of the first silicon die 140 before being transmitted over the jumper optical fibers 132 to an optical network. The optical amplifier may be configured to amplify optical signals received from an optical network by way of the jumper optical fibers 132 before the optical signals are further manipulated by the optical components of the first silicon die 140. Alternately or additionally, the optical amplifier may amplify optical signals generated by the laser diode before the optical signals are sent over the jumper optical fibers 132 to an optical network. In some embodiments, the optical components 134 may include one of the laser diode and the optical amplifier, but not both. Modifications, additions, or omissions may be made to the chip package 100 without departing from the scope of the present disclosure.

FIG. 1B illustrates a cross-sectional view of the example chip package 100 of FIG. 1A, arranged in accordance with at least one embodiment described herein. The first, second, and third silicon dies 140, 150, and 160 are arranged generally in a plane on a first surface of the substrate 120. The second silicon die 150 is arranged along the plane between the first and third silicon dies 140 and 160.

The third silicon die 160 may be associated with first and second electrical couplers 162a and 162b. The first electrical coupler 162a may electrically couple the third silicon die 160 to the first traces 152. The second electrical coupler 162b may electrically couple the third silicon die 160 to a through via 114. The first and second electrical couplers 162a and 162b may be wires, metal bumps, or some other configuration of a conductive material to electrically couple the third silicon die 160 to other components in the chip package 100.

The through via 114 may electrically couple the second electrical coupler 162b to an external signal port 112 that is outside the encapsulation 110 of the chip package 100. The external signal port 112 may be configured to allow electrical signals to be passed to and from the third silicon die 160 from and to outside the chip package 100. In some embodiments, the second electrical coupler 162b may be coupled to the external signal port 112 by a conductive element that is not the through via 114, such as a wire or trace.

The second silicon die 150 may be associated with first and second electrical couplers 154a and 154b. The first electrical coupler 154a may electrically couple the second silicon die 150 to the first traces 152. The second electrical coupler 154b may electrically couple the second silicon die 150 to a second trace 144. In some embodiments, the second trace 144 may be referred to as a transmission line. The second trace 144 may be formed in the substrate 120. The first and second electrical couplers 154a and 154b may be wires, metal bumps, or some other configuration of a conductive material to electrically couple the second silicon die 150 to other components in the chip package 100.

The first silicon die 140 may be associated with a first electrical coupler 142a that electrically couples a through via 146 that passes through the first silicon die 140 to the second trace 144. In some embodiments, the through via 146 may be electrically coupled to a wire 141. The wire 141 may electrically couple the through via 146 to the optical components 134. In particular, the wire 141 may electrically couple a laser diode of the optical components 134 to the through via 146. In some embodiments, the through via 146 may be electrically coupled to conductive material on the first silicon die 140. For example, the conductive material may electrically couple the through via 146 to a photodiode formed on the first silicon die 140. Alternately or additionally, the conductive material may electrically couple the through via 146 to an optical multiplexer formed on the first silicon die 140 that is controlled using electrical signals. Alternately or additionally, the conductive material may electrically couple the through via 146 to other optical components of the first silicon die 140 or the optical components 134. In some embodiments, a support 138 may support the jumper optical fibers 132 as the jumper optical fibers 132 extend between the first silicon die 140 and the optical fiber connector 130.

An example operation of the chip package 100 follows when the through via 146 is electrically coupled to the wire 141. A digital signal may be received by the third silicon die 160 by way of the second electrical coupler 162b. The processing unit on the third silicon die 160 may process the digital signal and send the processed digital signal along the first traces 152 to the second silicon die 150. One or more electrical circuits of the second silicon die 150 may process the processed digital signal. For example, the processed digital signal may be converted to an analog signal by a DAC on the second silicon die 150. The analog signal may then be conditioned for the laser diode of the optical components 134 by another electrical circuit on the second silicon die 150. The conditioned analog signal may be sent from the second silicon die 150 to the laser diode of the optical components 134 by way of the second trace 144 and the through via 146. The laser diode may generate an optical signal based on the conditioned analog signal, which may be an electrical signal. The optical signal may be manipulated by the photonics circuitry of the first silicon die 140 and transmitted over the jumper optical fibers 132 to an optical network. Alternately or additionally, a laser diode may be included on the first silicon die 140. In these and other embodiments, a signal from the second silicon die 150 may drive the laser diode. The output of the laser diode on the first silicon die 140 may drive an optical laser in the optical components 134 that generates optical signals that are transmitted over the jumper optical fibers 132.

Another example operation of the chip package 100 follows when the through via 146 is electrically coupled to a metal layer or trace formed on the first silicon die 140. An optical signal may be received over the jumper optical fibers 132 from an optical network. The optical signal may be manipulated by the photonic circuitry in the first silicon die 140 and converted to an electrical signal, e.g., an analog signal, by a photodiode in the first silicon die 140. The analog signal may be sent to the second silicon die 150 along the second trace 144. The electrical circuitry in the second silicon die 150 may condition the analog signal. Conditioning the analog signal may involve using a transimpedance amplifier, an equalizer, a clock and data recovery circuit (CDR), among other electrical circuitry. The analog signal may also be converted to a digital signal. The digital signal may be sent to the third silicon die 160 for processing along the first traces 152.

As illustrated in FIG. 1B, the third silicon die 160 is physically separated from the first and second silicon dies 140 and 150. In particular, the distance between the third silicon die is larger than the distance between the first and second silicon dies 140 and 150. By separating the third silicon die 160 from the first silicon die 140, a temperature of the first silicon die 140 may be less affected by heat generated by the third silicon die 160 during operation. Because the photonic circuitry included on the first silicon die 140 may be affected by temperature, reducing temperature changes in the first silicon die 140 may be desirable.

Separating the third silicon die 160 from the first silicon die 140 may also increase a physical distance that signals, such as analog or digital signals, travel between the first and third silicon dies 140 and 160. In the chip package 100, a physical distance that a signal travels between the first and second silicon dies 140 and 150 may be shorter than a physical distance that the signal travels between the second and third silicon dies 150 and 160. In some embodiments, the physical distance that the signal travels between the first and second silicon dies 140 and 150 may be an order of magnitude shorter than a physical distance that the signal travels between the second and third silicon dies 150 and 160.

The physical distance that a signal travels between the first and second silicon dies 140 and 150 may be a distance such that data may be recovered from the signal at an acceptable error rate for operation of an optical network to which the chip package 100 is coupled. When the signals are high data rate signals, the signals traversing a longer distance, such as the distance between the second and third silicon dies 140 and 150 may affect the integrity of the signals, such that data may not be recoverable from the signals. The electrical circuitry on the second silicon die 150 may therefore condition the signal from the first silicon die 140 such that the distance between the second and third silicon dies 150 and 160 may be traversed by the conditioned signal and the associated data may still be recovered from the conditioned signal at an acceptable error rate for operation of an optical network to which the chip package 100 is coupled. As a result, the chip package 100 may include a processing unit and photonic circuitry in the same encapsulated chip for optical signals with data rates over 10 Gbps. Modifications, additions, or omissions may be made to the chip package 100 without departing from the scope of the present disclosure.

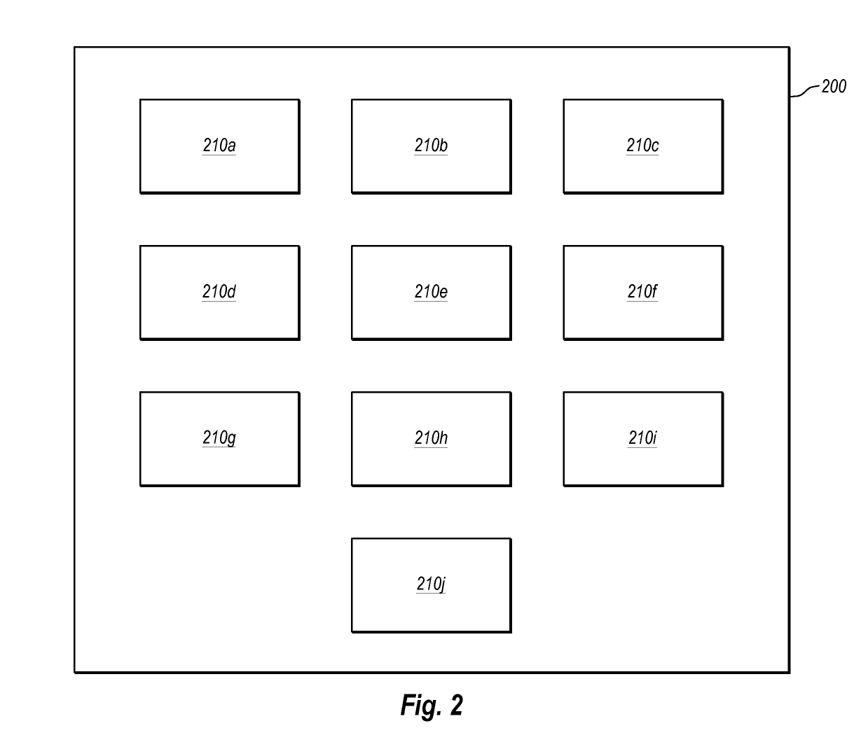

FIG. 2 illustrates an example silicon die 200, arranged in accordance with at least one embodiment described herein. The silicon die 200 may be formed to include electronic circuits 210 configured to support photonic operations performed by photonic components, such as a photodiode, a laser diode, an optical multiplexer, among others. The silicon die 200 may be an example of the second silicon die 150 of FIG. 1. In some embodiments, the silicon die 200 may include a transimpedance amplifier 210a, a driver 210b, CDR 210c, a clock synthesizer circuit 210d, a multiplexer 210e, a demultiplexer 210f, an analog-to-digital converter 210g, a digital-to-analog converter 210h, a temperature sensor 210i, control logic 210j for the photonic operations performed by the first silicon die 140, among other circuitry. In general, the electronic circuits 210 may be configured to generate analog signals from digital signals that may be used to generate optical signals and/or condition analog signals derived from optical signals.

The silicon die 200 may be manufactured using a variety of silicon processing techniques. For example, the silicon die 200 may be manufactured using a 14 nm process, 22 nm process, 32 nm process, 45 nm process, 65 nm process, 90 nm process, 130 nm process, 180 nm process, 250 nm process, or another process on silicon wafers of varying sizes. Modifications, additions, or omissions may be made to the silicon die 200 without departing from the scope of the present disclosure. For example, the silicon die 200 may include more than or fewer than the electronic circuits 210 illustrated in FIG. 2.

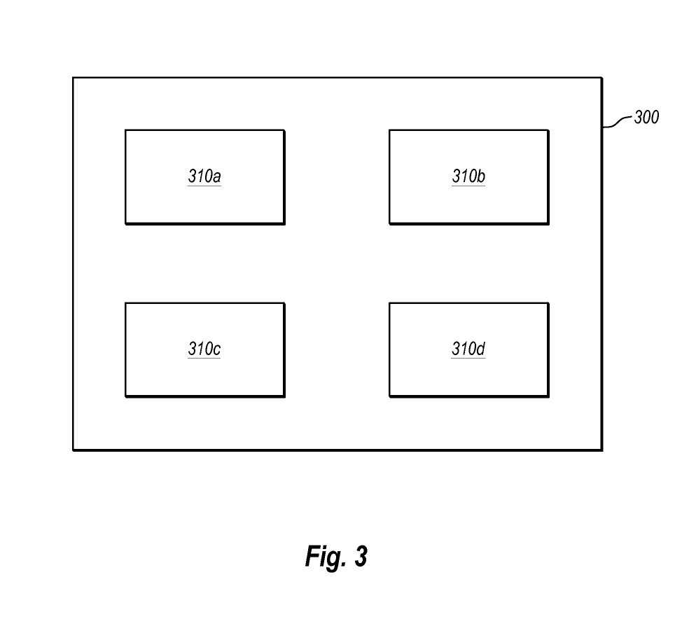

FIG. 3 illustrates another example silicon die 300, arranged in accordance with at least one embodiment described herein. The silicon die 300 may be formed to include photonics circuitry. The silicon die 300 may be an example of the first silicon die 140 of FIG. 1. In this and other embodiments, the photonics circuitry may use silicon as an optical medium to affect optical signals. For example, the silicon die 300 may include optical components 310 formed in silicon that manipulate optical signals. Alternately or additionally, the optical components 310 may be used for receiving optical signals transmitted over an optical network and converting the optical signals to analog signals. The optical components 310 may include one or more of a photodiode 310a, an optical multiplexer 310b, an optical modulator 310c, an optical demultiplexer 310d, among other optical components.

The silicon die 300 may be manufactured using a variety of silicon processing techniques. For example, the silicon die 300 may be manufactured using a 65 nm process, 90 nm process, 130 nm process, 180 nm process, 250 nm process, or another process on silicon wafers of varying sizes. Modifications, additions, or omissions may be made to the silicon die 300 without departing from the scope of the present disclosure. For example, the silicon die 300 may include more than or fewer than the optical components 310 illustrated in FIG. 2.

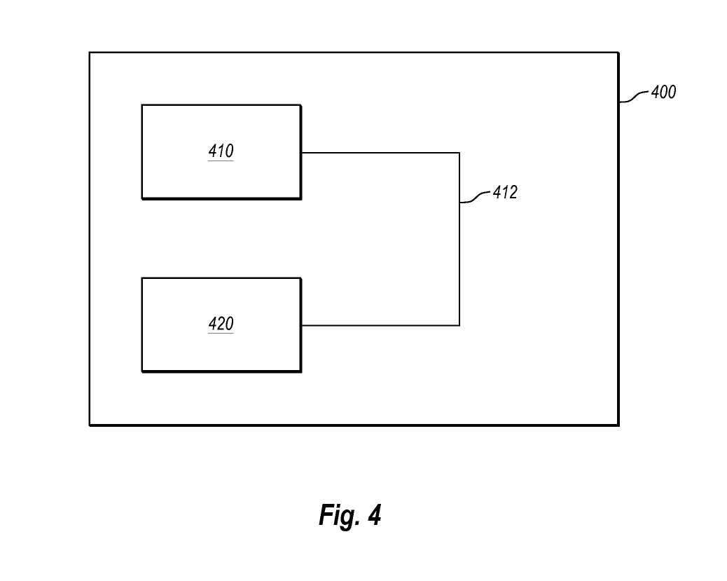

FIG. 4 illustrates another example silicon die 400, arranged in accordance with at least one embodiment described herein. The silicon die 400 may be formed to include a processing unit 410 that is a VLSI processing unit configured to process digital signals based on received instructions from a set of instructions for the processing unit 410. The silicon die 400 may be an example of the third silicon die 160 of FIG. 1. The silicon die 400 may also include memory 420 and an interconnect 412 between the memory 420 and the processing unit 410. The memory 420 may store data and instructions to be performed by the processing unit 410 and/or data that has been processed by the processing unit 410.

The silicon die 400 may be manufactured using a variety of silicon processing techniques. For example, the silicon die 400 may be manufactured using a 14 nm process, 22 nm process, 32 nm process, 45 nm process, 65 nm process, 90 nm process, 130 nm process, 180 nm process, 250 nm process, or another process on silicon wafers of varying sizes. Modifications, additions, or omissions may be made to the silicon die 400 without departing from the scope of the present disclosure.

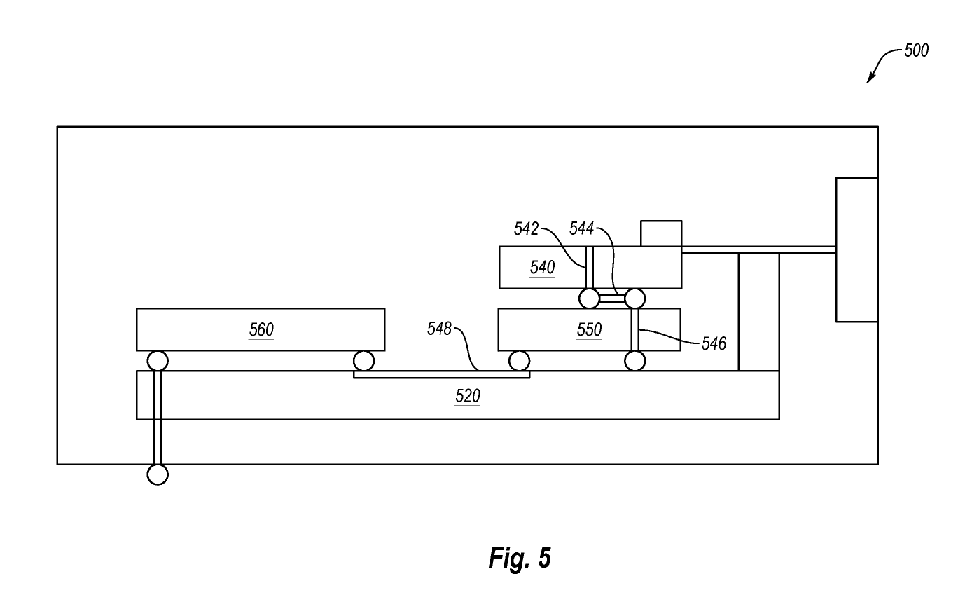

FIG. 5 illustrates a cross-sectional view of another example chip package 500, arranged in accordance with at least one embodiment described herein. The chip package 500 may include a first silicon die 540, a second silicon die 550, and a third silicon die 560. The first, second, and third silicon dies 540, 550, and 560 may be formed independently, using the same or different processing techniques. The first, second, and third silicon dies 540, 550, and 560 may be analogous to the first, second, and third silicon dies 140, 150, and 160 of FIGS. 1A and 1B.

In the chip package 500, the first, second, and third silicon dies 540, 550, and 560 may be supported by a substrate 520. As illustrated, the second and third silicon dies 550 and 560 may be supported directly by the substrate 520. Alternately or additionally, one or more other materials may separate the substrate 520 and the second and third silicon dies 550 and 560.

The first silicon die 540 may be supported by the second silicon die 550 such that the second silicon die 550 is between the first silicon die 540 and the substrate 520. In these and other embodiments, all of or a portion of the first and second silicon dies 540 and 550 may be aligned in two dimensions.

The third silicon die 560 may be electrically coupled to the second silicon die 550 by a first trace 548 formed in the substrate 520 between the second and third silicon dies 550 and 560. The second silicon die 550 may be electrically coupled to the first silicon die 540 by a first through via 546 that extends at least partially through the second silicon die 550, by a second trace 544 between the first and second silicon dies 540 and 550, and by a second through via 542 that extends at least partially through the first silicon die 540.

Modifications, additions, or omissions may be made to the chip package 500 without departing from the scope of the present disclosure.

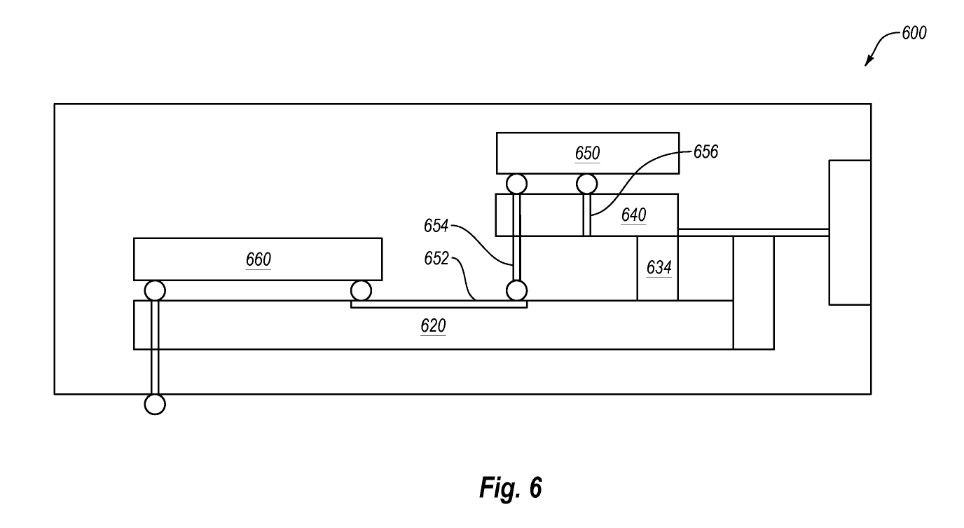

FIG. 6 illustrates a cross-sectional view of another example chip package 600, arranged in accordance with at least one embodiment described herein. The chip package 600 may include a first silicon die 640, a second silicon die 650, and a third silicon die 660. The first, second, and third silicon dies 640, 650, and 660 may be formed independently, using the same or different processing techniques. The first, second, and third silicon dies 640, 650, and 660 may be analogous to the first, second, and third silicon dies 140, 150, and 160 of FIG. 1A.

In the chip package 600, the first, second, and third silicon dies 640, 650, and 660 may be supported by a substrate 620. As illustrated, the third silicon die 660 may be supported directly by the substrate 620. Alternately or additionally, one or more other materials may separate the substrate 620 and the third silicon die 660.

The second silicon die 650 may be supported by the first silicon die 640 such that the first silicon die 640 is between the second silicon die 650 and the substrate 620. In these and other embodiments, all of or a portion of the first and second silicon dies 640 and 650 may be aligned in two dimensions. Furthermore, optical components 634, which may be analogous to the optical components 134 of FIG. 1, may be between the substrate 620 and the first silicon die 640.

The third silicon die 660 may be electrically coupled to the second silicon die 650 by a first trace 652 formed in the substrate 620 between the second and third silicon dies 650 and 660 and a through via 654 that extends through the first silicon die 640. The second silicon die 650 may be electrically coupled to the first silicon die 640 by a second through via 656 that extends at least partially through the first silicon die 640.

Modifications, additions, or omissions may be made to the chip package 600 without departing from the scope of the present disclosure.

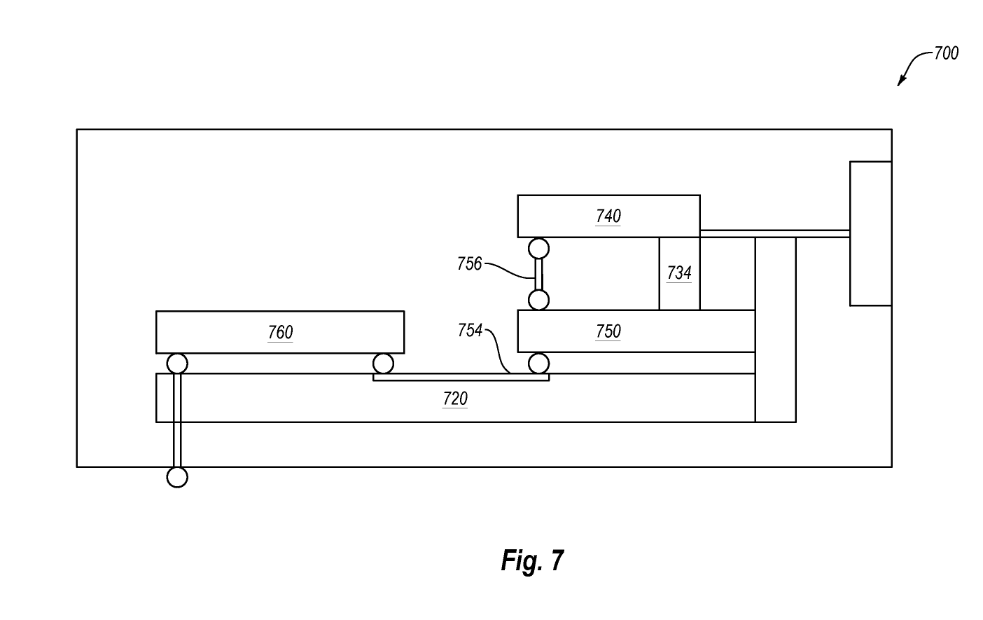

FIG. 7 illustrates a cross-sectional view of another example chip package 700, arranged in accordance with at least one embodiment described herein. The chip package 700 may include a first silicon die 740, a second silicon die 750, and a third silicon die 760. The first, second, and third silicon dies 740, 750, and 760 may be formed independently, using the same or different processing techniques. The first, second, and third silicon dies 740, 750, and 760 may be analogous to the first, second, and third silicon dies 140, 150, and 160 of FIG. 1A.

In the chip package 700, the first, second, and third silicon dies 740, 750, and 760 may be supported by a substrate 720. As illustrated, the second and third silicon dies 750 and 760 may be supported directly by the substrate 720. Alternately or additionally, one or more other materials may separate the substrate 720 and the second and third silicon dies 750 and 760.

The first silicon die 740 may be supported by the second silicon die 750 such that the second silicon die 750 is between the first silicon die 740 and the substrate 720. In these and other embodiments, all of or a portion of the first and second silicon dies 740 and 750 may be aligned in two dimensions. Additionally, optical components 734 may be located between the first and second silicon dies 740 and 705. The optical components 734 may be analogous to the optical components 134 of FIG. 1A.

The third silicon die 760 may be electrically coupled to the second silicon die 750 by a first trace 754 formed in the substrate 720 between the second and third silicon dies 750 and 760. The second silicon die 750 may be electrically coupled to the first silicon die 740 by an electrical coupler 756 that extends between the second silicon die 750 and the first silicon die 740.

Modifications, additions, or omissions may be made to the chip package 700 without departing from the scope of the present disclosure.

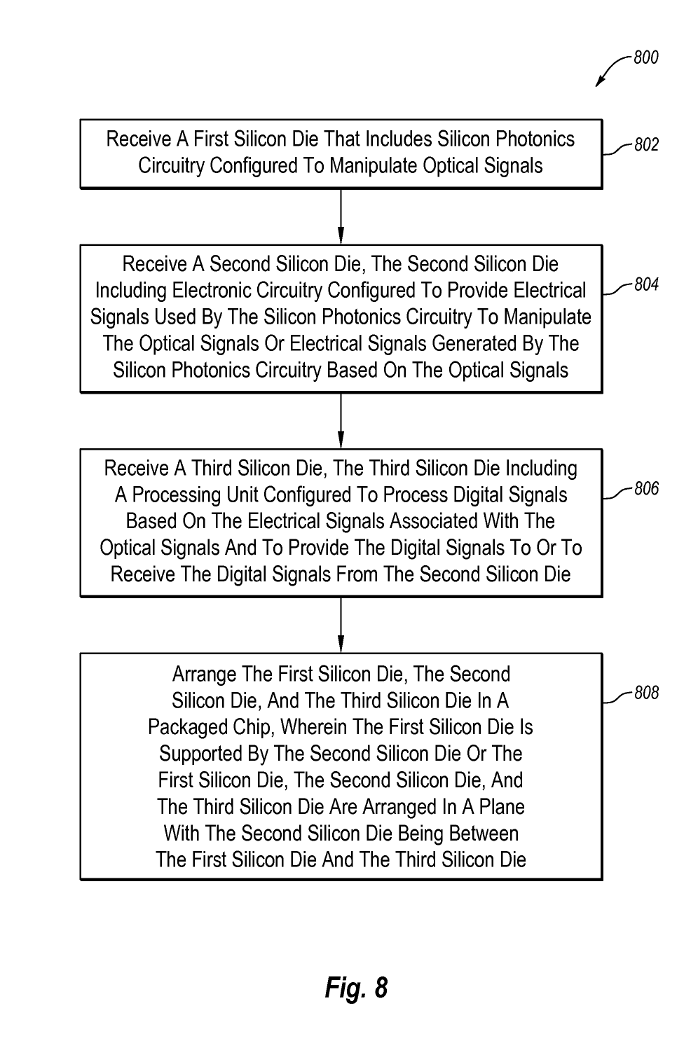

FIG. 8 illustrates a flow diagram of an example method 800 of forming an interposer of an IC chip package, arranged in accordance with at least one embodiment described herein. Although illustrated as discrete blocks, various blocks may be divided into additional blocks, combined into fewer blocks, or eliminated, depending on the desired implementation.

The method may begin at block 802 in which a first silicon die is received that may include silicon photonics circuitry configured to manipulate optical signals. In some embodiments, the silicon photonics circuitry may include one or more of a photodiode, an optical multiplexer, an optical modulator, an optical demultiplexer, among other optical components.

In block 804, a second silicon die is received. The second silicon die may include electronic circuitry configured to provide electrical signals used by the silicon photonics circuitry to manipulate the optical signals or electrical signals generated by the silicon photonics circuitry based on the optical signals. In some embodiments, the electronic circuitry may include one or more of a transimpedance amplifier, a driver, a clock and data recovery circuit, a clock synthesizer circuit, a multiplexer, a demultiplexer, an ADC, a DAC, a temperature sensor, control logic for the silicon photonics circuitry, among other circuitry.

In block 806, a third silicon die may be received. The third silicon die may include a processing unit configured to process digital signals based on the electrical signals associated with the optical signals and to provide the digital signals to or to receive the digital signals from the second silicon die. In some embodiments, the processing unit may be a very large-scale integration processing unit configured to process digital signals based on received instructions from a set of instructions for the processing unit.

In block 808, the first silicon die, the second silicon die, and the third silicon die may be arranged in a packaged chip. In some embodiments, the first silicon die may be supported by the second silicon die. Alternately or additionally, the first silicon die, the second silicon die, and the third silicon die may be arranged in a plane with the second silicon die being between the first silicon die and the third silicon die. In some embodiments, the packaged chip may operate as an optical receiver, an optical transmitter, or an optical transceiver. Examples of the different arrangements of the first, second, and third silicon dies are given with respect to FIGS. 1B, and 5-7.

One skilled in the art will appreciate that, for this and other processes and methods disclosed herein, the functions performed in the processes and methods may be implemented in differing order. Furthermore, the outlined steps and operations are only provided as examples, and some of the steps and operations may be optional, combined into fewer steps and operations, or expanded into additional steps and operations without detracting from the essence of the disclosed embodiments.

For example, the method 800 may further include forming a substrate that supports the first silicon die, the second silicon die, and the third silicon die and forming transmission lines (e.g., traces described above) in the substrate that couple the second silicon die and the third silicon die. In some embodiments, the first silicon die may be supported by the second silicon die and the substrate such that the second silicon die may be located between the first silicon die and the substrate.

The method 800 may further include positioning an optical fiber connector configured to couple to an optical cable in the packaged chip. Alternately or additionally, the method 800 may include positioning one or more optical fibers to couple the first silicon die to the optical fiber connector. In these and other embodiments, the optical signals manipulated by the silicon photonics circuitry may be configured to transverse the optical fibers.

All examples and conditional language recited herein are intended for pedagogical objects to aid the reader in understanding the invention and the concepts contributed by the inventor to furthering the art, and are to be construed as being without limitation to such specifically recited examples and conditions. Although embodiments of the present inventions have been described in detail, it should be understood that the various changes, substitutions, and alterations could be made hereto without departing from the spirit and scope of the invention.

1. A chip package comprising:
a first silicon die including silicon photonics circuitry configured to manipulate optical signals;
a second silicon die electrically coupled to the first silicon die, the second silicon die including electronic circuitry configured to provide electrical signals used by the silicon photonics circuitry to manipulate the optical signals or electrical signals generated by the silicon photonics circuitry based on the optical signals; and
a third silicon die electrically coupled to the second silicon die by one or more transmission lines, the third silicon die including a processing unit configured to process digital signals based on the electrical signals associated with the optical signals and to provide the digital signals to or to receive the digital signals from the second silicon die.

2. The chip package of claim 1, further comprising an optical fiber connector configured to couple to an optical cable, wherein the first silicon die is coupled to the optical fiber connector by one or more optical fibers and the optical signals manipulated by the silicon photonics circuitry are configured to transverse the optical fibers.

3. The chip package of claim 1, further comprising a substrate supporting the second silicon die and the third silicon die, the one or more transmission lines between the second and third silicon dies being formed in the substrate.

4. The chip package of claim 3, wherein the first silicon die, the second silicon die, and the third silicon die are located directly over the substrate.

5. The chip package of claim 3, wherein the first silicon die is coupled to the second silicon die such that the second silicon die is between the substrate and the first silicon die.

6. The chip package of claim 3, wherein outer electrical connectors of the first silicon die are on a first side of the first silicon die that is opposite a second side of the first silicon die, the second side of the first silicon die being adjacent to the substrate.

7. The chip package of claim 3, wherein the substrate is a silicon substrate.

8. The chip package of claim 1, wherein the first silicon die includes one or more through-silicon-vias that electrically connect the first silicon die to the second silicon die.

9. The chip package of claim 1, further comprising a laser driver and/or optical amplifier coupled to the first silicon die.

10. The chip package of claim 1, wherein the processing unit is a very large scale integration (VLSI) processing unit configured to process digital signals based on received instructions from a set of instructions for the processing unit.

11. The chip package of claim 1, wherein the silicon photonics circuitry includes one or more of a photodiode, an optical multiplexer, an optical modulator, and an optical demultiplexer.

12. The chip package of claim 1, wherein the electronic circuitry includes one or more of a transimpedance amplifier, a driver, a clock and data recovery circuit, a clock synthesizer circuit, a multiplexer, a demultiplexer, an analog-to-digital converter, a digital-to-analog converter, a temperature sensor, and control logic for the silicon photonics circuitry.

13. The chip package of claim 1, wherein the packaged chip operates as an optical receiver, an optical transmitter, or an optical transceiver.

14.-20. (canceled)
